(19) United States
(12) Patent Application Publication
(10) Pub. No.: US 2025/0259858 A1
(43) Pub. Date: Aug. 14, 2025

(54) SYSTEMS AND METHODS FOR WAFER LEVEL STACKED SI PACKAGE FORMATION

(71) Applicant: Meta Platforms Technologies, LLC, Menlo Park, CA (US)

(72) Inventor: Rajendra D Pendse, Fremont, CA (US)

(21) Appl. No.: 19/048,427

(22) Filed: Feb. 7, 2025

Related U.S. Application Data
(60) Provisional application No. 63/551,143, filed on Feb. 8, 2024.

(51) Int. Cl. H01L 21/48; H01L 21/56; H01L 21/683; H01L 23/00; H01L 23/31; H01L 23/538; H01L 25/07; H10B 80/00

(52) U.S. Cl. CPC H01L 21/4853; H01L 21/6836; H01L 23/538; H01L 25/074; H01L 21/563; H01L 23/3128; H01L 24/16; H01L 24/48; H01L 2224/16227; H01L 2224/48227; H01L 2225/0651; H01L 2225/06517; H10B 80/00

(57) ABSTRACT

The disclosed method may include using a wafer-level process to build up a plurality of redistribution layers. The method may additionally include wafer-level mounting a plurality of flip chip die atop the plurality of redistribution layers. The method may also include wafer-level wire bonding the plurality of flip chip die to the plurality of redistribution layers. Various other methods, systems, and computer-readable media are also disclosed.

### CROSS REFERENCE TO RELATED APPLICATION

This application claims the benefit of U.S. Provisional Application No. 63/551,143, filed Feb. 8, 2024, the disclosure of which is incorporated, in its entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow diagram of exemplary methods for wafer-level stacked Si package formation.

FIG. 2 provides block diagrams illustrating various semiconductor devices formed at various stages of one or more of the methods of FIG. 1.

FIG. 3 provides block diagrams illustrating various semiconductor device packages formed at various stages of one or more of the methods of FIG. 1.

FIG. 4 provides block diagrams illustrating various semiconductor devices and semiconductor device packages formed at various stages of one or more of the methods of FIG. 1.

FIG. 5 provides block diagrams illustrating various semiconductor device packages formed at various stages of one or more of the methods of FIG. 1.

FIG. 6 is a block diagram illustrating a semiconductor device package formed according to one or more methods of FIG. 1.

FIG. 7 is an illustration of exemplary augmented-reality glasses that may be used in connection with embodiments of this disclosure.

FIG. 8 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

The present disclosure is generally directed to systems and methods for wafer level stacked semiconductor device (Si) package formation. For example, by building up redistribution (RDL) layers using wafer level processing and performing stacking and wire bonding of dies (e.g., chips, chiplets, etc.) as a wafer level process, a semiconductor device package can be formed. The resulting semiconductor device package can be twenty-percent thinner than traditional packages that use a laminate substrate and can accommodate more than two times as much wiring/routing between chips and from the chips to external pins of the package. With such a laminate substrate, increasing wiring density and reducing thickness would require stretching the incumbent laminate-based technology, resulting in poor manufacturability and high cost.

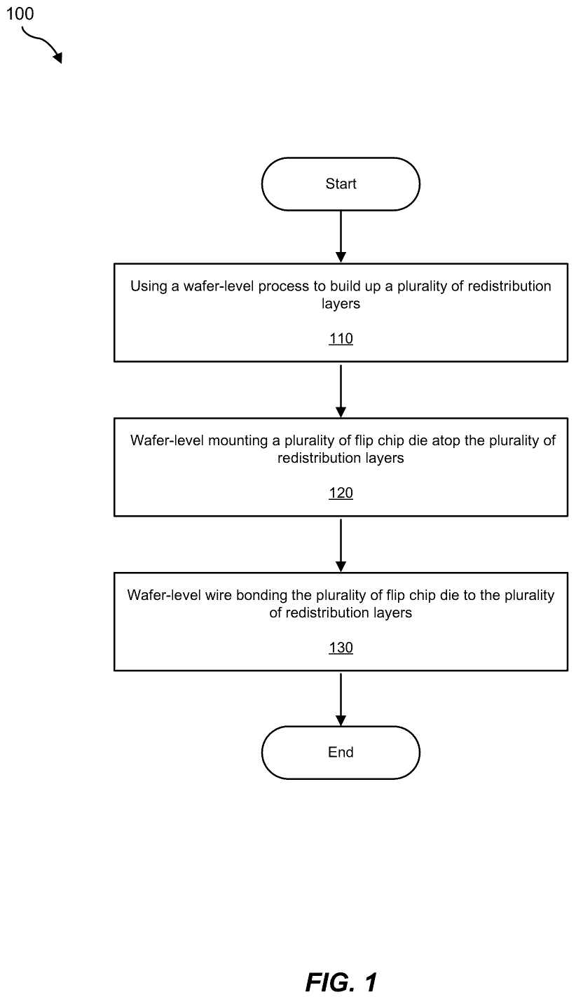

FIG. 1 illustrates methods 100 for wafer-level stacked Si package formation. Method 100 may be carried out by humans and/or machines (e.g., workstations, chemical chambers, etc.) in various environments (e.g., clean rooms, etc.). Semiconductor device packages may be structured according to various packaging processes, such as substrate-level packaging processes or wafer-level packaging processes. For example, substrate-level packaging processes may employ a substrate to facilitate the assembly and connection of components on a base material. The substrate may ensure mechanical support, electrical pathways, and heat dissipation for integrated circuits (ICs) and electronic devices. Materials like silicon, ceramics, laminate structures, and organic compounds may be used based on specific needs.

Wafer-level packaging is a process in integrated circuit manufacturing in which packaging components may be attached to an integrated circuit (IC) before the wafer-on which the IC is fabricated—is diced. For example, the top and bottom layers of the packaging and the solder bumps may be attached to the integrated circuits while they are still in the wafer. This process differs from a process like substrate level packaging in which the wafer may be sliced into individual circuits (e.g., dice) before the packaging components are attached.

As shown in FIG. 1 at step 110, method 100 may include using a wafer-level process. For example, method 100 may, at step 110, include using a wafer-level process to build up a plurality of redistribution layers.

Method 100 may, at step 110, include using the wafer-level process to build up the plurality of redistribution layers in various ways. For example, method 100 may, at step 110, include building up a thin film redistribution layer substrate. In this context, the thin film redistribution layer substrate may exhibit a thickness no greater than 0.03 millimeters. Additionally or alternatively, the thin film redistribution layer substrate may exhibit a line/space no greater than 5 μm/5 μm. Additionally or alternatively, the thin film redistribution layer substrate may exhibit a via pad size no greater than 35 μm. In another example, method 100 may, at step 110, include building up the plurality of redistribution layers on a carrier wafer.

The term “line/space,” as used herein, may generally refer to the width of metal traces and the space between them in the redistribution layer (RDL) of a semiconductor. For example, and without limitation, the RDL may be a layer of conductive metal (e.g., copper, solder, etc.) connection lines that are redistributed from one location to die pads on a die.

The term “via pad,” as used herein, may generally refer to a printed circuit board (PCB) manufacturing technique that involves placing a via, or plated hole, directly in or under a surface mount component's solder pad. For example, and without limitation, a via pad may be used to reduce the overall footprint of components on a board, which may be beneficial for modern, compact electronic devices.

As shown in FIG. 1 at step 120, method 100 may include wafer-level mounting. For example, method 100 may, at step 120, include wafer-level mounting a plurality of flip chip die atop the plurality of redistribution layers.

The term “flip chip die,” as used herein, may generally refer to a stack of one or more die that includes a flip chip. For example, and without limitation, a flip chip may include a single die atop which additional die may be stacked (e.g., back-to-back). In this context, a first die (e.g., a logic die) may be mounted face down on a substrate (e.g., a thin film redistribution layer (RDL) substrate) and one or more additional die (e.g., a second die, a DRAM, etc.) may be stacked face up atop the first die. In some implementations, a back side of the first die and a backside of the second die may be attached to one another (e.g., by an adhesive layer).

Method 100 may, at step 120, perform wafer-level mounting in a variety of ways. For example, method 100 may, at step 120, include mounting the plurality of flip chip die face down atop the plurality of redistribution layers. In this context, method 100 may, at step 120, include inverting a chip to bring solder dots on a face of the chip down onto connectors or pads on an underlying substrate. In this context, the thin film redistribution layer substrate may be used in place of a laminate substrate (e.g., made of printed circuit board layers). The solder may then be re-melted to produce an electrical connection, typically using a thermosonic bonding or reflow solder process. Additionally, the mounting may be wafer-level in the sense that it occurs before the thin film redistribution layer substrate (e.g., and wafer carrier) are singulated (e.g., diced apart), to form separate semiconductor devices. Moreover, the flip chip die may include more than one semiconductor die (e.g., two die, a dynamic random access memory (DRAM) stacked atop a logic die, etc.) stacked back-to-back using an adhesive layer. In this context, one of the die may be mounted face to face to the thin film redistribution layer substrate, whereas another of the die may be connected to the thin film redistribution layer substrate in another manner (e.g., by wire bonding in step 130).

perform wafer-level wire bonding in a variety of ways. For example, method 100 may, at step 120, include using thin metallic bond wires, typically made of gold, aluminum, or copper, that are thermally or ultrasonically connected to chip terminals on one end, and to the thin film redistribution layer substrate on the other end. Wire bonding types can include ball bonding and/or wedge bonding. In this context, ball bonding is a process that typically uses gold wire, and a small ball is formed at the end of the wire and attached to a bond pad using heat and pressure while another end of the wire is connected to the chip package using ultrasonic energy. In contrast, wedge bonding is a process that often uses aluminum wire that may be threaded through a capillary and pressed against a bond pad at room temperature without forming a ball. Additionally, the wire bonding may be wafer-level in the sense that it occurs before the thin film redistribution layer substrate (e.g., and wafer carrier) are singulated (e.g., diced apart), to form separate semiconductor devices.

Method 100 may, at step 130, perform additional procedures. For example, method 100 may, at step 130, include singulating the plurality of flip chip die after the wafer-level mounting and the wafer-level wire bonding. Alternatively or additionally, method 100 may, at step 130, include subjecting the plurality of flip chip die to a molding process after the wafer-level mounting and the wafer-level wire bonding. In some implementations, method 100 may, at step 130, include singulating the plurality of flip chip die after subjecting the plurality of flip chip die to the molding process. In this context, the molding process may include wafer-level compression molding. In other implementations, method 100 may, at step 130, include subjecting the plurality of flip chip die to the molding process after singulating the plurality of flip chip die. In this context, the molding process may include transfer molding (e.g., of a singulated strip). In additional or alternative implementations, method 100 may, at step 130, include removing a carrier wafer, after singulating the plurality of flip chip die, from a first side of the thin film redistribution layer substrate that is opposite a second side of the thin film redistribution layer substrate to which at least one flip chip die of the plurality of flip chip die is mounted. In this context, method 100 may, at step 130, include attaching a plurality of conductive balls (e.g., copper, solder, etc.) to the first side of the thin film redistribution layer substrate after removing the carrier wafer.

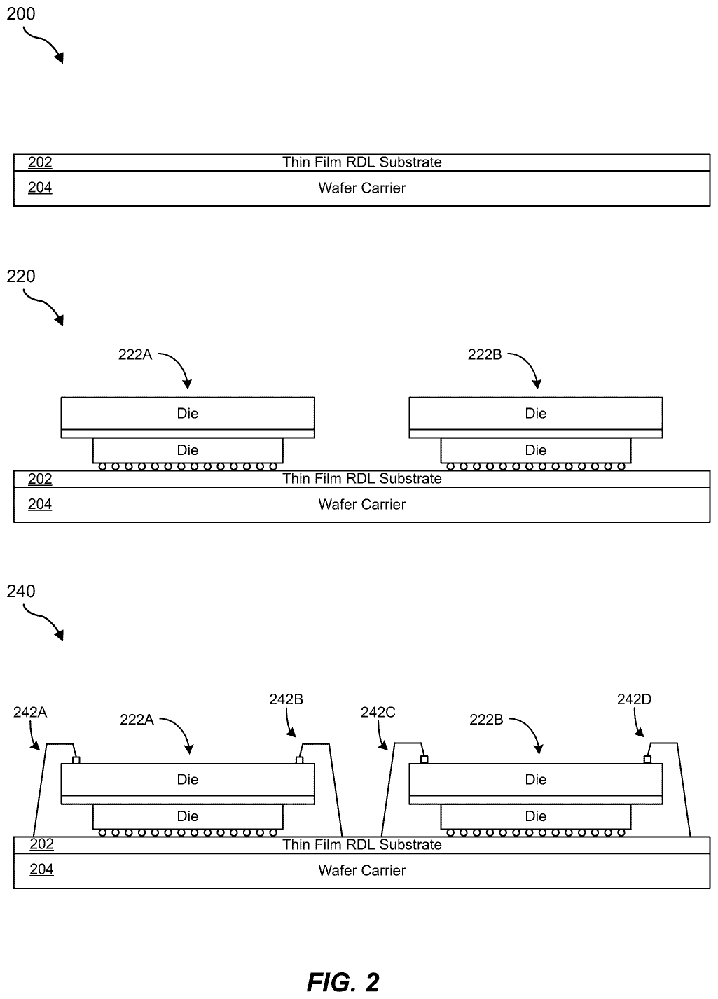

FIG. 2 illustrates various semiconductor devices 200, 220, and 240 formed at various stages of one or more of the methods of FIG. 1. For example, semiconductor device 200 may be formed as a result of step 110 of FIG. 1, in which a wafer-level process is used to build up a plurality of redistribution layers to form a thin film redistribution layer substrate 202 on a wafer carrier 204. Additionally, semiconductor device 220 may be formed as a result of step 120 of FIG. 1, in which a plurality of flip chip die 222A and 222B may be wafer-level mounted atop the thin film redistribution layer substrate 202 formed atop wafer carrier 204. Also, semiconductor device 240 may be formed as a result of step 130 of FIG. 1, in which the plurality of flip chip die may be wafer-level wire bonded to the plurality of redistribution layers.

As shown in FIG. 2, semiconductor device 240 may include a wafer carrier 204, a thin film redistribution layer substrate 202 on the wafer carrier 204, and a plurality of flip chip die 222A and 222B mounted atop the thin film redistribution layer substrate and wire bonded to the thin film redistribution layer substrate. Additionally, the thin film redistribution layer substrate 202 may exhibit a thickness no greater than 0.03 millimeters. Alternatively or additionally, the thin film redistribution layer substrate 202 may exhibit a line/space no greater than 5 μm/5 μm. Additionally or alternatively, the thin film redistribution layer substrate 202 may exhibit a via pad size no greater than 35 μm.

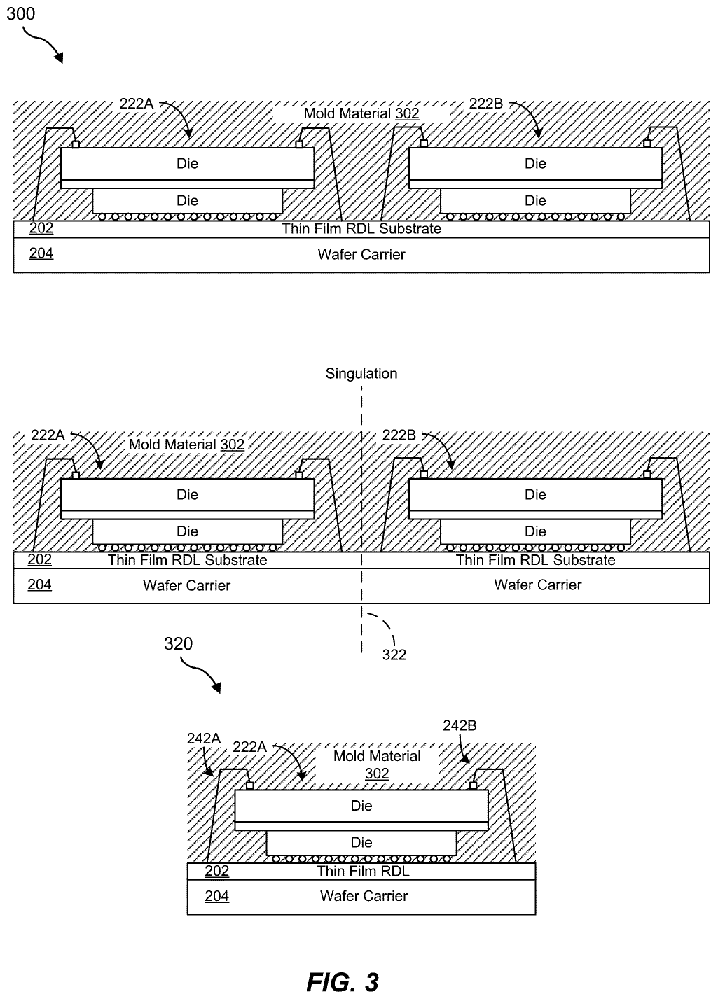

FIG. 3 illustrates various semiconductor device packages 300 and 320 formed at various stages of one or more of the methods of FIG. 1. For example, semiconductor device package 300 may be formed as a result of step 130 of FIG. 1, in which the plurality of flip chip die 222A and 222B may be subjected to a molding process. In this context, the molding process may correspond to wafer-level compression molding that may cover the flip chip die 222A and 222B and the thin film redistribution layer substrate 202 with mold material 302 (e.g., an adhesive, a metal, etc.). Additionally, semiconductor device package 320 may be formed as a result of step 130 of FIG. 1, in which the plurality of flip chip die may be singulated (e.g., diced apart) after the plurality of flip chip die 222A and 222B are subjected to the molding process. In this context, singulating the plurality of flip chip die 222A and 222B may include separating the mold material 302, the thin film redistribution layer substrate 202, and the wafer carrier 204 at a location 322 that is positioned in between the plurality of flip chip die 222A and 222B.

As shown in FIG. 3, semiconductor device package 320 may include a wafer carrier 204, a thin film redistribution layer substrate 202 on the wafer carrier 204, and a flip chip die 222A mounted atop the thin film redistribution layer substrate 202. Additionally, the flip chip die 222A may be wire bonded to the thin film redistribution layer substrate 202 by wire bonds 242A and 242B. Also, the thin film redistribution layer substrate 202 may exhibit a thickness no greater than 0.03 millimeters. Alternatively or additionally, the thin film redistribution layer substrate 202 may exhibit a line/space no greater than 5 μm/5 μm. Additionally or alternatively, the thin film redistribution layer substrate 202 may exhibit a via pad size no greater than 35 μm.

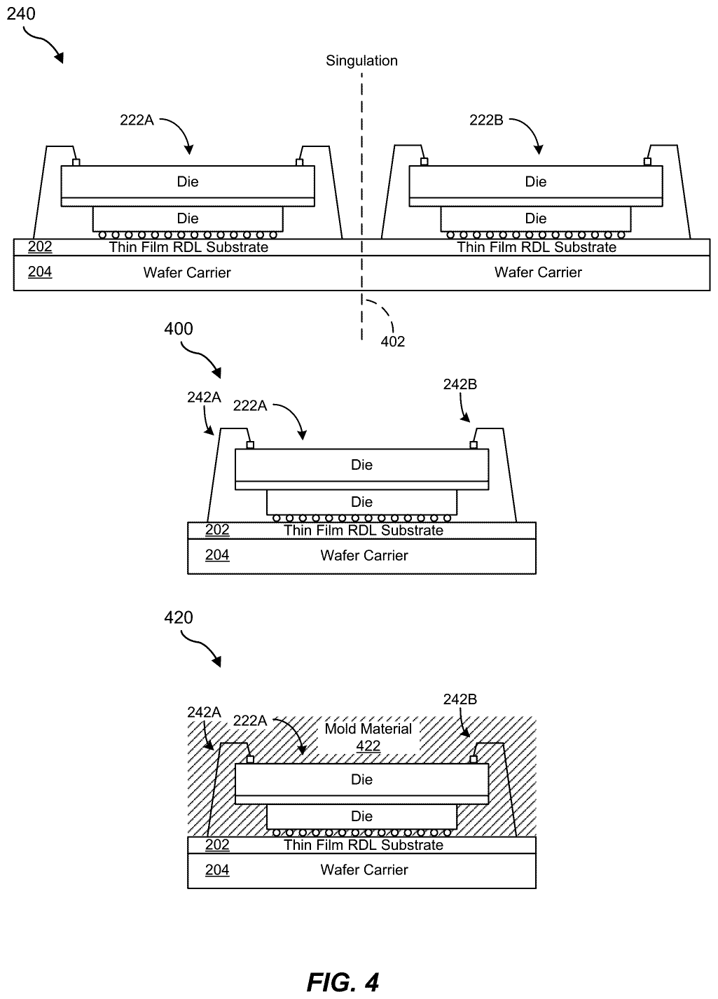

FIG. 4 illustrates various semiconductor devices 400 and semiconductor device packages 420 formed at various stages of one or more of the methods of FIG. 1. For example, semiconductor device 400 may be formed as a result of step 130 of FIG. 1, in which the plurality of flip chip die 222A and 222B of semiconductor device 240 of FIG. 2 may be singulated (e.g., diced apart) without first subjecting the plurality of flip chip die 222A and 222B to a molding process. In this context, singulating the plurality of flip chip die 222A and 222B may include separating the thin film redistribution layer substrate 202, and the wafer carrier 204 at a location 402 that is positioned in between the plurality of flip chip die 222A and 222B.

As shown in FIG. 4, semiconductor device package 420 may be formed as a result of step 130 of FIG. 1, in which the flip chip die 222A may be subjected to a molding process after singulating the plurality of flip chip die 222A and 222B. In this context, the molding process may include transfer molding (e.g., of a singulated strip). For example, the transfer molding may cover the flip chip die 222A and the thin film redistribution layer substrate 202 with mold material 422 (e.g., an adhesive, a metal, etc.).

As shown in FIG. 4, semiconductor device package 420 may include a wafer carrier 204, a thin film redistribution layer substrate 202 on the wafer carrier 204, and a flip chip die 222A mounted atop the thin film redistribution layer substrate 202. Additionally, the flip chip die 222A may be wire bonded to the thin film redistribution layer substrate 202 by wire bonds 242A and 242B. Also, the thin film redistribution layer substrate 202 may exhibit a thickness no greater than 0.03 millimeters. Alternatively or additionally, the thin film redistribution layer substrate 202 may exhibit a line/space no greater than 5 μm/5 μm. Additionally or alternatively, the thin film redistribution layer substrate 202 may exhibit a via pad size no greater than 35 μm.

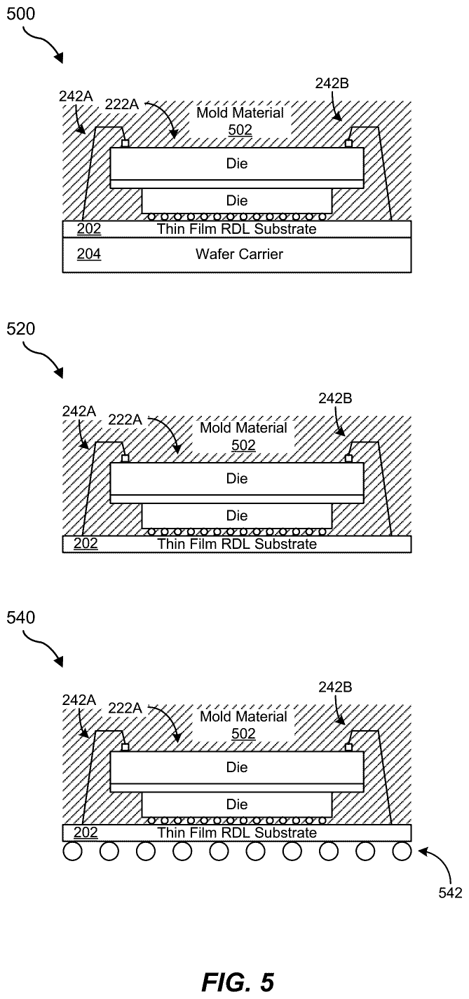

FIG. 5 illustrates various semiconductor device packages 500, 520, and 540 formed at various stages of one or more of the methods of FIG. 1. For example, semiconductor device package 500 may correspond to semiconductor device package 320 of FIG. 3 or semiconductor device package 420 of FIG. 4. In this context, semiconductor device package 500 may include thin film redistribution layer substrate 202 on wafer carrier 204, flip chip die 222A, wire bonds 242A and 242B, and mold material 502, which may correspond to mold material 302 of FIG. 3 or mold material 422 of FIG. 4.

As shown in FIG. 5, semiconductor device package 520 may be formed as a result of step 130 of FIG. 1, in which wafer carrier 204 may be removed (e.g., mechanically, by etching, etc.) from a first side of the thin film redistribution layer substrate 202 that is opposite a second side of the thin film redistribution layer substrate 202 to which flip chip die 222A is mounted. Thus, semiconductor device package 520 may include a thin film redistribution layer substrate 202, a flip chip die 222A mounted atop the thin film redistribution layer substrate 202 and wire bonded to the thin film redistribution layer substrate 202 by wire bonds 242A and 242B, and mold material 502 covering the flip chip die 222A and the thin film redistribution layer substrate 202. The thin film redistribution layer substrate 202 may exhibit a thickness no greater than 0.03 millimeters, may exhibit a line/space no greater than 5 μm/5 μm, and/or may exhibit a via pad size no greater than 35 μm.

As shown in FIG. 5, semiconductor device package 540 may be formed as a result of step 130 of FIG. 1, in which a plurality of conductive balls 542 (e.g., copper, solder, etc.) may be attached to the first side of the thin film redistribution layer substrate 202 after removing the wafer carrier 204. Thus, semiconductor device package 540 may include a thin film redistribution layer substrate 202, a flip chip die 222A mounted atop the thin film redistribution layer substrate 202 and wire bonded to the thin film redistribution layer substrate 202 by wire bonds 242A and 242B, mold material 502 covering the flip chip die 222A and the thin film redistribution layer substrate 202, and the plurality of conductive balls 542 attached to the first side of the thin film redistribution layer substrate 202 that is opposite a second side of the thin film redistribution layer substrate 202 to which the flip chip die 222A is mounted. The thin film redistribution layer substrate 202 may exhibit a thickness no greater than 0.03 millimeters, may exhibit a line/space no greater than 5 μm/5 μm, and/or may exhibit a via pad size no greater than 35 μm.

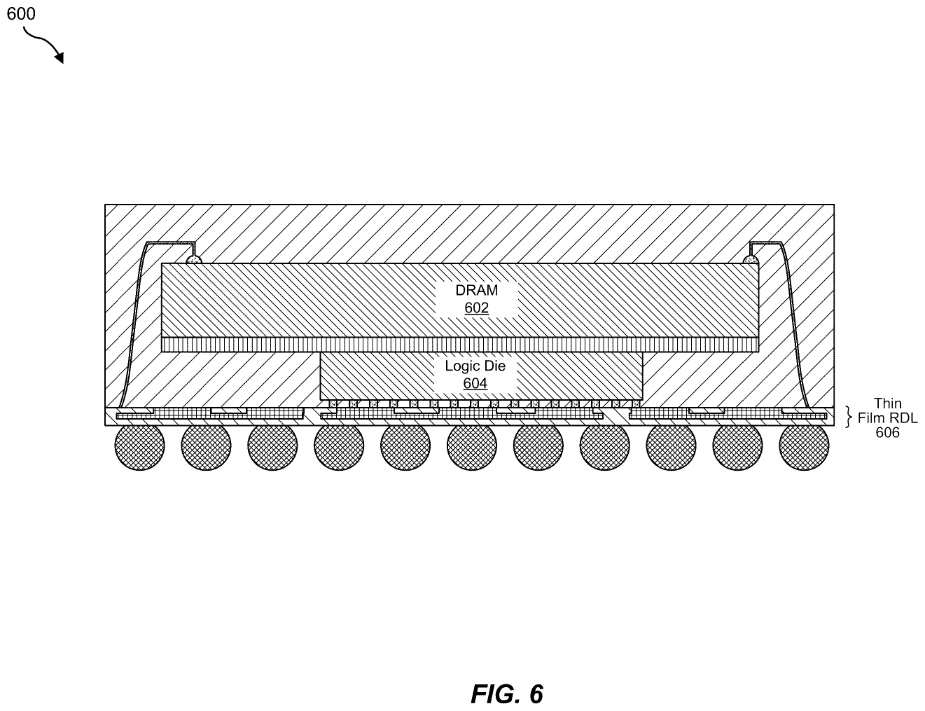

FIG. 6 illustrates example semiconductor device package 600. As shown in FIG. 6, semiconductor device package 600 can be used in the industry for many applications such as stacking a DRAM die 602 on a Logic die 604, wherein the Logic die 604 is a cellular modem chip, an applications processor (AP), or another chip. Semiconductor device package 600 can include thin layers of wafer-level redistribution layers (RDL) 606 instead of a laminate substrate. Replacing the laminate substrate with RDL 606 can result in a substrate that is four times thinner and more than two times denser in terms of circuit and wiring density. As a result, semiconductor device package 600 can be twenty percent thinner and can accommodate more than two times as much wiring/routing between the chips and from the chips to external pins. The process of forming semiconductor device package 600 can include building up the RDL 606 layers using wafer level processing and performing the stacking and wire bonding as a wafer level process. Thus, the process of forming semiconductor device package 600 can represent a unique fusion of wire bonding and wafer level processing technologies in a single package. The resulting package architecture can be a compelling solution for not only custom Si products but also for Si procured from partners and in the broader industry at large in areas such as APs, 5G Modems, and many others.

In the example semiconductor device package 600 of FIG. 6, semiconductor device package 600 can have a package thickness of approximately 0.60 mm with a substrate thickness of 0.03 mm. This example thickness can represent an approximate twenty-percent reduction in thickness. Additionally, semiconductor device package 600 can have a wiring density of approximately 5 μm/5 μm line/space with a via pad of 35 μm. This example wiring density can represent an approximately sixty-percent increase in density. Also, semiconductor device package 600 can have a substrate structure corresponding to thin film RDL. Further, semiconductor device package 600 can be formed according to a fabrication process corresponding to die assembly at a wafer-level on a thin film RDL and molding corresponding to a wafer-level mold or transfer mold of a singulated (e.g., cut, diced, etc.) strip. Accordingly, semiconductor device package 600 can achieve a twenty percent thinner package with sixty percent greater wiring density using a thin film RDL substrate and a wafer-level on thin film RDL fabrication process with either wafer level molding or transfer level molding of a singulated strip. Thus, the semiconductor device package 600 is able to achieve increased wiring density and reduced thickness while being manufacturable and cost effective. The smaller package thickness and higher wiring density can enable higher performance and miniaturization of a device, resulting in an improved user experience.

As set forth above, the disclosed systems and methods provide a way to combine a wafer level packaging approach with wire bonding technology to realize a smaller form factor (FF) package with significantly higher wiring density. Instead of a laminate substrate, the disclosed systems and methods can utilize wafer-level redistribution layer (RDL) routing layers, and molding can be performed with either a wafer-level molding process or a traditional transfer molding process by singulating the wafer into strips that are compatible with the transfer molding processes.

### EXAMPLE EMBODIMENTS

Example 1: A method may include using a wafer-level process to build up a plurality of redistribution layers, wafer-level mounting a plurality of flip chip die atop the plurality of redistribution layers, and wafer-level wire bonding the plurality of flip chip die to the plurality of redistribution layers.

Example 2: The method of example 1, wherein the using the wafer-level process to build up the plurality of redistribution layers includes building up a thin film redistribution layer substrate.

Example 3: The method of any of examples 1 or 2, wherein the thin film redistribution layer substrate exhibits a thickness no greater than 0.03 millimeters.

Example 4: The method of any of examples 1-3, wherein the thin film redistribution layer substrate exhibits a line/space no greater than 5 μm/5 μm.

Example 5: The method of any of examples 1-4, wherein the thin film redistribution layer substrate exhibits a via pad size no greater than 35 μm.

Example 6: The method of any of examples 1-5, wherein using the wafer-level process to build up the plurality of redistribution layers includes building up the plurality of redistribution layers on a carrier wafer.

Example 7: The method of any of examples 1-6, wherein the wafer-level mounting includes mounting the plurality of flip chip die face down atop the plurality of redistribution layers.

Example 8: The method of any of examples 1-7, further including singulating the plurality of flip chip die after the wafer-level mounting and the wafer-level wire bonding.

Example 9: The method of any of examples 1-8, further including subjecting the plurality of flip chip die to a molding process after the wafer-level mounting and the wafer-level wire bonding.

Example 10: The method of any of examples 1-9, wherein singulating the plurality of flip chip die occurs after subjecting the plurality of flip chip die to the molding process.

Example 11: The method of any of examples 1-10, wherein the molding process includes wafer-level compression molding.

Example 12: The method of any of examples 1-11, wherein subjecting the plurality of flip chip die to the molding process occurs after singulating the plurality of flip chip die.

Example 13: The method of any of examples 1-12, wherein the molding process includes transfer molding.

Example 14: The method of any of examples 1-13, wherein using the wafer-level process to build up the plurality of redistribution layers includes building up a thin film redistribution layer substrate on a carrier wafer, the method further including removing the carrier wafer, after singulating the plurality of flip chip die, from a first side of the thin film redistribution layer substrate that is opposite a second side of the thin film redistribution layer substrate to which at least one flip chip die of the plurality of flip chip die is mounted.

Example 15: The method of any of examples 1-14, further including attaching a plurality of conductive balls to the first side of the thin film redistribution layer substrate after removing the carrier wafer.

Example 16: A semiconductor device may include a wafer carrier, a thin film redistribution layer substrate on the wafer carrier, and a plurality of flip chip die mounted atop the thin film redistribution layer substrate and wire bonded to the thin film redistribution layer substrate.

Example 17: The semiconductor device of example 16, wherein the thin film redistribution layer substrate exhibits a thickness no greater than 0.03 millimeters, exhibits a line/space no greater than 5 μm/5 μm, and/or exhibits a via pad size no greater than 35 μm.

Example 18: A semiconductor device package may include a thin film redistribution layer substrate, a flip chip die mounted atop the thin film redistribution layer substrate and wire bonded to the thin film redistribution layer substrate, and mold material covering the flip chip die and the thin film redistribution layer substrate.

Example 19: The semiconductor device package of example 18, wherein the thin film redistribution layer substrate exhibits a thickness no greater than 0.03 millimeters, exhibits a line/space no greater than 5 μm/5 μm, and/or exhibits a via pad size no greater than 35 μm.

Example 20: The semiconductor device package of any of examples 18 or 19, further including a plurality of conductive balls attached to a first side of the thin film redistribution layer substrate that is opposite a second side of the thin film redistribution layer substrate to which the flip chip die is mounted.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

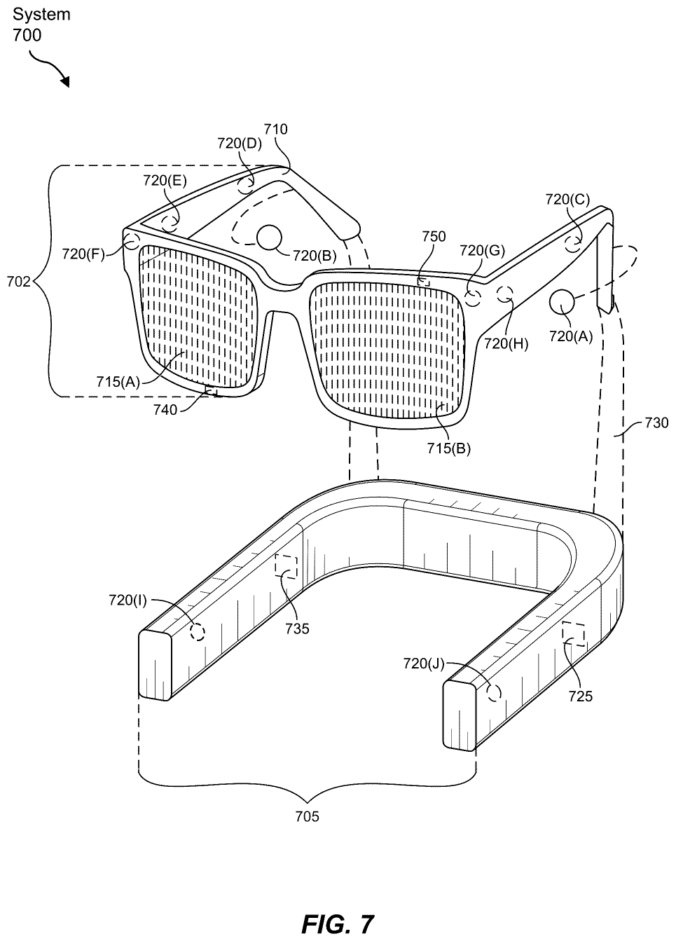

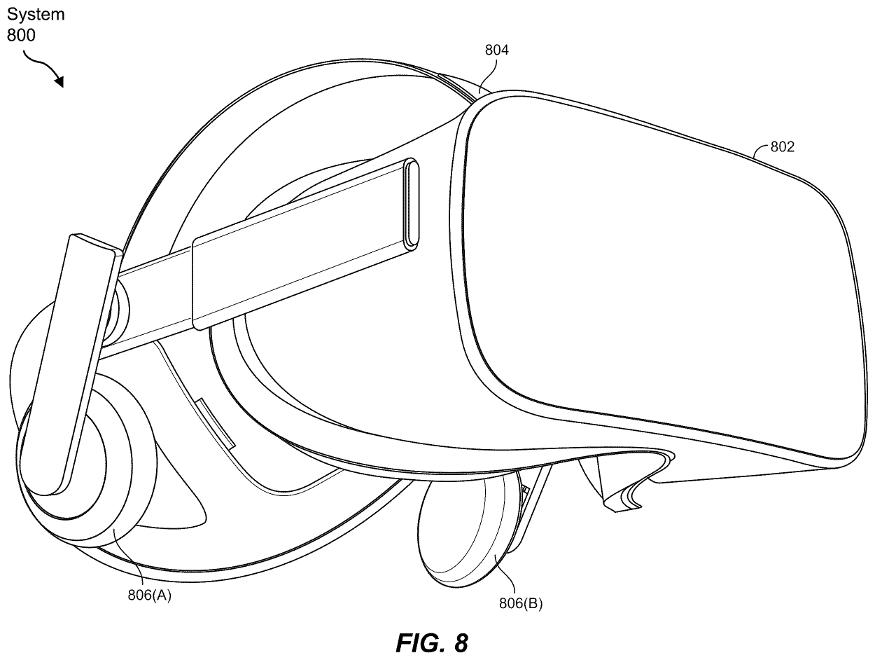

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 700 in FIG. 7) or that visually immerses a user in an artificial reality (such as, e.g., virtual-reality system 800 in FIG. 8). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

FIG. 7 is an illustration of exemplary augmented reality glasses that may be used in connection with embodiments of this disclosure. As shown in FIG. 7, augmented-reality system 700 may include an eyewear device 702 with a frame 710 configured to hold a left display device 715(A) and a right display device 715(B) in front of a user's eyes. Display devices 715(A) and 715(B) may act together or independently to present an image or series of images to a user. While augmented-reality system 700 includes two displays, embodiments of this disclosure may be implemented in augmented-reality systems with a single NED or more than two NEDs.

In some embodiments, augmented-reality system 700 may include one or more sensors, such as sensor 740. Sensor 740 may generate measurement signals in response to motion of augmented-reality system 700 and may be located on substantially any portion of frame 710. Sensor 740 may represent one or more of a variety of different sensing mechanisms, such as a position sensor, an inertial measurement unit (IMU), a depth camera assembly, a structured light emitter and/or detector, or any combination thereof. In some embodiments, augmented-reality system 700 may or may not include sensor 740 or may include more than one sensor. In embodiments in which sensor 740 includes an IMU, the IMU may generate calibration data based on measurement signals from sensor 740. Examples of sensor 740 may include, without limitation, accelerometers, gyroscopes, magnetometers, other suitable types of sensors that detect motion, sensors used for error correction of the IMU, or some combination thereof.

In some examples, augmented-reality system 700 may also include a microphone array with a plurality of acoustic transducers 720(A)-720(J), referred to collectively as acoustic transducers 720. Acoustic transducers 720 may represent transducers that detect air pressure variations induced by sound waves. Each acoustic transducer 720 may be configured to detect sound and convert the detected sound into an electronic format (e.g., an analog or digital format). The microphone array in FIG. 7 may include, for example, ten acoustic transducers: 720(A) and 720(B), which may be designed to be placed inside a corresponding ear of the user, acoustic transducers 720(C), 720(D), 720(E), 720(F), 720(G), and 720(H), which may be positioned at various locations on frame 710, and/or acoustic transducers 720(I) and 720(J), which may be positioned on a corresponding neckband 705.

In some embodiments, one or more of acoustic transducers 720(A)-(J) may be used as output transducers (e.g., speakers). For example, acoustic transducers 720(A) and/or 720(B) may be earbuds or any other suitable type of headphone or speaker.

The configuration of acoustic transducers 720 of the microphone array may vary. While augmented-reality system 700 is shown in FIG. 2 as having ten acoustic transducers 720, the number of acoustic transducers 720 may be greater or less than ten. In some embodiments, using higher numbers of acoustic transducers 720 may increase the amount of audio information collected and/or the sensitivity and accuracy of the audio information. In contrast, using a lower number of acoustic transducers 720 may decrease the computing power required by an associated controller 750 to process the collected audio information. In addition, the position of each acoustic transducer 720 of the microphone array may vary. For example, the position of an acoustic transducer 720 may include a defined position on the user, a defined coordinate on frame 710, an orientation associated with each acoustic transducer 720, or some combination thereof.

Acoustic transducers 720(A) and 720(B) may be positioned on different parts of the user's ear, such as behind the pinna, behind the tragus, and/or within the auricle or fossa. Or, there may be additional acoustic transducers 720 on or surrounding the ear in addition to acoustic transducers 720 inside the ear canal. Having an acoustic transducer 720 positioned next to an ear canal of a user may enable the microphone array to collect information on how sounds arrive at the ear canal. By positioning at least two of acoustic transducers 720 on either side of a user's head (e.g., as binaural microphones), augmented-reality device 700 may simulate binaural hearing and capture a 3D stereo sound field around about a user's head. In some embodiments, acoustic transducers 720(A) and 720(B) may be connected to augmented-reality system 700 via a wired connection 730, and in other embodiments acoustic transducers 720(A) and 720(B) may be connected to augmented-reality system 700 via a wireless connection (e.g., a BLUETOOTH connection). In still other embodiments, acoustic transducers 720(A) and 720(B) may not be used at all in conjunction with augmented-reality system 700.

Acoustic transducers 720 on frame 710 may be positioned in a variety of different ways, including along the length of the temples, across the bridge, above or below display devices 715(A) and 715(B), or some combination thereof. Acoustic transducers 720 may also be oriented such that the microphone array is able to detect sounds in a wide range of directions surrounding the user wearing the augmented-reality system 700. In some embodiments, an optimization process may be performed during manufacturing of augmented-reality system 700 to determine relative positioning of each acoustic transducer 720 in the microphone array.

In some examples, augmented-reality system 700 may include or be connected to an external device (e.g., a paired device), such as neckband 705. Neckband 705 generally represents any type or form of paired device. Thus, the following discussion of neckband 705 may also apply to various other paired devices, such as charging cases, smart watches, smart phones, wrist bands, other wearable devices, hand-held controllers, tablet computers, laptop computers, other external compute devices, etc.

As shown, neckband 705 may be coupled to eyewear device 702 via one or more connectors. The connectors may be wired or wireless and may include electrical and/or non-electrical (e.g., structural) components. In some cases, eyewear device 702 and neckband 705 may operate independently without any wired or wireless connection between them. While FIG. 7 illustrates the components of eyewear device 702 and neckband 705 in example locations on eyewear device 702 and neckband 705, the components may be located elsewhere and/or distributed differently on eyewear device 702 and/or neckband 705. In some embodiments, the components of eyewear device 702 and neckband 705 may be located on one or more additional peripheral devices paired with eyewear device 702, neckband 705, or some combination thereof.

Pairing external devices, such as neckband 705, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 700 may be provided by a paired device or shared between a paired device and an eyewear device, thus reducing the weight, heat profile, and form factor of the eyewear device overall while still retaining desired functionality. For example, neckband 705 may allow components that would otherwise be included on an eyewear device to be included in neckband 705 since users may tolerate a heavier weight load on their shoulders than they would tolerate on their heads. Neckband 705 may also have a larger surface area over which to diffuse and disperse heat to the ambient environment. Thus, neckband 705 may allow for greater battery and computation capacity than might otherwise have been possible on a stand-alone eyewear device. Since weight carried in neckband 705 may be less invasive to a user than weight carried in eyewear device 702, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 705 may be communicatively coupled with eyewear device 702 and/or to other devices. These other devices may provide certain functions (e.g., tracking, localizing, depth mapping, processing, storage, etc.) to augmented-reality system 700. In the embodiment of FIG. 7, neckband 705 may include two acoustic transducers (e.g., 720(l) and 720(J)) that are part of the microphone array (or potentially form their own microphone subarray). Neckband 705 may also include a controller 725 and a power source 735.

Acoustic transducers 720(l) and 720(J) of neckband 705 may be configured to detect sound and convert the detected sound into an electronic format (analog or digital). In the embodiment of FIG. 7, acoustic transducers 720(l) and 720(J) may be positioned on neckband 705, thereby increasing the distance between the neckband acoustic transducers 720(l) and 720(J) and other acoustic transducers 720 positioned on eyewear device 702. In some cases, increasing the distance between acoustic transducers 720 of the microphone array may improve the accuracy of beamforming performed via the microphone array. For example, if a sound is detected by acoustic transducers 720(C) and 720(D) and the distance between acoustic transducers 720(C) and 720(D) is greater than, e.g., the distance between acoustic transducers 720(D) and 720(E), the determined source location of the detected sound may be more accurate than if the sound had been detected by acoustic transducers 720(D) and 720(E).

Controller 725 of neckband 705 may process information generated by the sensors on neckband 705 and/or augmented-reality system 700. For example, controller 725 may process information from the microphone array that describes sounds detected by the microphone array. For each detected sound, controller 725 may perform a direction-of-arrival (DOA) estimation to estimate a direction from which the detected sound arrived at the microphone array. As the microphone array detects sounds, controller 725 may populate an audio data set with the information. In embodiments in which augmented-reality system 700 includes an inertial measurement unit, controller 725 may compute all inertial and spatial calculations from the IMU located on eyewear device 702. A connector may convey information between augmented-reality system 700 and neckband 705 and between augmented-reality system 700 and controller 725. The information may be in the form of optical data, electrical data, wireless data, or any other transmittable data form. Moving the processing of information generated by augmented-reality system 700 to neckband 705 may reduce weight and heat in eyewear device 702, making it more comfortable to the user.

Power source 735 in neckband 705 may provide power to eyewear device 702 and/or to neckband 705. Power source 735 may include, without limitation, lithium-ion batteries, lithium-polymer batteries, primary lithium batteries, alkaline batteries, or any other form of power storage. In some cases, power source 735 may be a wired power source. Including power source 735 on neckband 705 instead of on eyewear device 702 may help better distribute the weight and heat generated by power source 735.

FIG. 8 is an illustration of an exemplary virtual-reality headset that may be used in connection with embodiments of this disclosure. As noted, some artificial-reality systems may, instead of blending an artificial reality with actual reality, substantially replace one or more of a user's sensory perceptions of the real world with a virtual experience. One example of this type of system is a head-worn display system, such as virtual-reality system 800 in FIG. 8, that mostly or completely covers a user's field of view. Virtual-reality system 800 may include a front rigid body 802 and a band 804 shaped to fit around a user's head. Virtual-reality system 800 may also include output audio transducers 806(A) and 806(B). Furthermore, while not shown in FIG. 8, front rigid body 802 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 700 and/or virtual-reality system 800 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 700 and/or virtual-reality system 800 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 700 and/or virtual-reality system 800 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A method comprising:
using a wafer-level process to build up a plurality of redistribution layers;
wafer-level mounting a plurality of flip chip die atop the plurality of redistribution layers; and
wafer-level wire bonding the plurality of flip chip die to the plurality of redistribution layers.

2. The method of claim 1, wherein the using the wafer-level process to build up the plurality of redistribution layers includes building up a thin film redistribution layer substrate.

3. The method of claim 2, wherein the thin film redistribution layer substrate exhibits a thickness no greater than 0.03 millimeters.

4. The method of claim 2, wherein the thin film redistribution layer substrate exhibits a line/space no greater than 5 μm/5 μm.

5. The method of claim 2, wherein the thin film redistribution layer substrate exhibits a via pad size no greater than 35 μm.

6. The method of claim 1, wherein using the wafer-level process to build up the plurality of redistribution layers includes building up the plurality of redistribution layers on a carrier wafer.

7. The method of claim 1, wherein the wafer-level mounting includes mounting the plurality of flip chip die face down atop the plurality of redistribution layers.

8. The method of claim 1, further comprising:
singulating the plurality of flip chip die after the wafer-level mounting and the wafer-level wire bonding.

9. The method of claim 8, further comprising:
subjecting the plurality of flip chip die to a molding process after the wafer-level mounting and the wafer-level wire bonding.

10. The method of claim 9, wherein singulating the plurality of flip chip die occurs after subjecting the plurality of flip chip die to the molding process.

11. The method of claim 10, wherein the molding process includes wafer-level compression molding.

12. The method of claim 9, wherein subjecting the plurality of flip chip die to the molding process occurs after singulating the plurality of flip chip die.

13. The method of claim 12, wherein the molding process includes transfer molding.

14. The method of claim 8, wherein using the wafer-level process to build up the plurality of redistribution layers includes building up a thin film redistribution layer substrate on a carrier wafer, the method further comprising:
removing the carrier wafer, after singulating the plurality of flip chip die, from a first side of the thin film redistribution layer substrate that is opposite a second side of the thin film redistribution layer substrate to which at least one flip chip die of the plurality of flip chip die is mounted.

15. The method of claim 14, further comprising:
attaching a plurality of conductive balls to the first side of the thin film redistribution layer substrate after removing the carrier wafer.

16. A semiconductor device, comprising:
a wafer carrier;
a thin film redistribution layer substrate on the wafer carrier; and
a plurality of flip chip die mounted atop the thin film redistribution layer substrate and wire bonded to the thin film redistribution layer substrate.

17. The semiconductor device of claim 16, wherein the thin film redistribution layer substrate at least one of:
exhibits a thickness no greater than 0.03 millimeters;
exhibits a line/space no greater than 5 μm/5 μm; or
exhibits a via pad size no greater than 35 μm.

18. A semiconductor device package, comprising:
a thin film redistribution layer substrate;
a flip chip die mounted atop the thin film redistribution layer substrate and wire bonded to the thin film redistribution layer substrate; and
mold material covering the flip chip die and the thin film redistribution layer substrate.

19. The semiconductor device package of claim 18, wherein the thin film redistribution layer substrate at least one of:
exhibits a thickness no greater than 0.03 millimeters;
exhibits a line/space no greater than 5 μm/5 μm; or
exhibits a via pad size no greater than 35 μm.

20. The semiconductor device package of claim 18, further comprising:
a plurality of conductive balls attached to a first side of the thin film redistribution layer substrate that is opposite a second side of the thin film redistribution layer substrate to which the flip chip die is mounted.
